(19) United States
(12) Patent Application Publication
(10) Pub. No.: US 2005/0016586 A1
(43) Pub. Date: Jan. 27, 2005

(54) Method for fabricating Pt-MOx nanophase electrodes for highly efficient dye-sensitiized solar cell

(75) Inventors: Seok-Soon Kim, Kwangju (KR); Kyung-Won Park, Kwangju (KR); Jun-Ho Yum, Kwangju (KR); Yung-Eun Sung, Kwangju (KR)

Correspondence Address: STERNE, KESSLER, GOLDSTEIN & FOX PLLC, 1100 NEW YORK AVENUE, N.W., WASHINGTON, DC, 20005, US

(73) Assignee: Kwangju Institute of Science and Technology, Kwangju (KR)

(21) Appl. No.: 10/762,479

(22) Filed: Jan. 23, 2004

(30) Foreign Application Priority Data
Jul. 22, 2003 (KR) 2003-0050234

(51) Int. Cl. H01L 31/00

(52) U.S. Cl. 136/263; 438/82

(57) ABSTRACT

A method for fabricating a counter electrode for a dye-sensitized solar cell includes co-sputtering platinum and a metal oxide as target materials to deposit nanocrystalline platinum and an amorphous metal oxide on the substrate. The counter electrode exhibits improved performances as an electro-catalyst to assist in the reduction of I₃⁻ during operation of a dye-sensitized solar cell.

### BACKGROUND OF THE INVENTION

1. Field of the Invention

The present invention relates to a method for fabricating a counter electrode for a dye-sensitized solar cell, and more particularly to a method for fabricating a counter electrode for a dye-sensitized solar cell wherein the counter electrode comprises nanocrystalline platinum (Pt) and an amorphous metal oxide deposited on the substrate and serves as an electro-catalyst to assist in the reduction of I₃⁻ during operation of a dye-sensitized solar cell. The counter electrode exhibits improved electro-catalytic performances.

2. Related Art

Dye-sensitized solar cells are novel devices of photo-electrochemical solar cells that can efficiently convert solar energy to electricity. The dye-sensitized solar cells are manufactured by chemically adsorbing a dye capable of forming electrons and holes when irradiated by light in the visible region, to a semiconductor material having a wide energy band gap. The dye-sensitized solar cells are manufactured at much lower cost than common commercial silicon solar cells and compound semiconductor solar cells. In addition, the dye-sensitized solar cells have a higher efficiency, compared to organic solar cells. Furthermore, the dye-sensitized solar cells have advantages in that they can be manufactured in an environmentally friendly manner.

When the dye-sensitized solar cells absorb incoming light, the dye is photo-excited and oxidized, to provide electrons to a conduction band of an oxide having a wide energy band. These electrons flow through an external electric circuit, and at the same time, the oxidized dye is reduced by accepting electrons from an electron donor (I⁻) present in an electrolyte and returns to its ground state. A redox mediator as an electron source for the reduction is converted from I₃⁻ to the electron donor (I⁻) with the help of a counter electrode acting as an electro-catalyst.

In order to prevent the electric power loss around the maximum electric power, the electro-catalytic performance of the counter electrode is very important. As the counter electrode, platinum electrodes are widely utilized in terms of their excellent catalytic properties. In this connection, a technique has been reported for maximizing the catalytic properties of platinum that forms a platinum cluster using the thermal decomposition of chloroplatinic acid (H₂PtCl₆) with a large active surface area. However, the counter electrode thus fabricated has poor uniformity and poor adhesion to a substrate, causing an increase in dark current (see N. Papageorgiou, W. F. Maier and M. Gratzel, J. Electrochem. Soc. 144:876-883 (1997)).

Studies on methods for fabricating platinum electrodes as counter electrodes by electron-beam evaporation and characteristics of counter electrodes fabricated by sputtering are being actively undertaken. However, the counter electrodes fabricated by electron-beam evaporation have disadvantages of highly dense film formation and poor adhesion to substrates. Although the counter electrodes fabricated by sputtering have excellent adhesion to substrates, proper porosity, and an appropriately large active surface area, the fabrication costs are considered high (see A. Hauch and A. Georg, Electrochim. Acta. 46:3457-3466 (2001)).

### SUMMARY OF THE INVENTION

Therefore, the present invention has been made in view of the above problems, and provides a method for fabricating a counter electrode for a dye-sensitized solar cell, wherein the counter electrode comprises nanocrystalline platinum and an amorphous metal oxide. The counter electrode of the present invention improves the efficiency of a solar cell.

There is provided a method for fabricating a counter electrode for a dye-sensitized solar cell by co-sputtering platinum and a metal oxide as target materials to deposit nanocrystalline platinum and an amorphous metal oxide on the substrate.

This co-sputtering process enables the fabrication of an electrode that includes two phases, i.e., a nanosized polycrystalline platinum phase and an amorphous metal oxide phase, deposited on the substrate by simultaneous evaporation of platinum and a metal oxide, while interfering with the growth of the platinum phase. A single target in the form of a mixture of platinum and a metal oxide is sputtered, to deposit a film composed of a platinum-metal oxide composite phase on the substrate.

The metal oxide used for co-sputtering can have a high refractive index, e.g., a refractive index of 2 or more. Representative examples of the metal oxide as a target material include oxides of titanium, chromium, zinc, copper, etc., all of which have a refractive index of 2 or more. When these highly refractive metal oxides are co-sputtered together with platinum, they increase the reflectance of light and thus promote the excitation of dyes used, thereby improving the efficiency of a solar cell.

In addition, the metal oxide can include highly conductive oxides. Examples of such metal oxide typically include oxides of ruthenium, vanadium, tin, indium, etc., all of which have an electric conductivity of 0.1 S/m or more. When these highly conductive metal oxides are co-sputtered together with platinum, they help the transfer of electrons from an external electric circuit and thus facilitate the prompt regeneration of I⁻, thereby improving the efficiency of a solar cell to be manufactured.

The metal oxide preferably includes oxides having an open structure. Examples of these metal oxide include oxides of tantalum, silicon, aluminum and other transition metals. The term “metal oxides having an open structure” refers to metal oxides having a crystalline structure in which relatively many pores are formed, unlike compact crystalline structures. When these open-structured metal oxides are co-sputtered together with platinum, they act as pathways of ions, such as I₃⁻ and I⁻ present in an electrolyte, and help to allow the platinum to participate in the regeneration of I⁻, thereby improving the efficiency of a solar cell to be manufactured.

### BRIEF DESCRIPTION OF THE DRAWINGS

FIG. 1 shows a co-sputtering system used to fabricate a counter electrode in the present invention.

FIG. 2 is a θ-2θ graph obtained by an X-ray diffraction (XRD) analysis of a platinum-nickel oxide prepared in Example 1.

FIGS. 3A and 3B are a transmission electron microscope (TEM) image (FIG. 3A) and a transmission electron diffraction (TED) pattern (FIG. 3B) of an electrode comprising nanocrystalline platinum and amorphous nickel oxide deposited on the substrate, which is fabricated in Example 1.

FIG. 4 is a graph showing the I—V (current-voltage) characteristics of an all-solid-state dye-sensitized solar cell manufactured using a counter electrode fabricated in Example 1.

FIG. 5 is a cyclic voltammogram (CV) for determining the active surface area of a counter electrode fabricated in Example 1.

FIG. 6 is an explanatory view showing increase in the excitation of a dye by the use of titanium oxide in Example 2.

FIG. 7 is a θ-2θ graph obtained by an X-ray diffraction (XRD) analysis of a platinum-nickel oxide prepared in Example 2.

FIGS. 8A and 8B are a transmission electron microscope (TEM) image (FIG. 8A) and a transmission electron diffraction (TED) pattern (FIG. 8B) of an electrode comprising nanocrystalline platinum and amorphous titanium oxide deposited on the substrate, which is fabricated in Example 2.

FIG. 9 is a graph showing the I—V (current-voltage) characteristics of an all-solid-state dye-sensitized solar cell manufactured using a counter electrode fabricated in Example 2.

FIG. 10 is a cyclic voltammogram (CV) for determining the active surface area of a counter electrode fabricated in Example 2.

FIG. 11 is a graph showing a reflectance of a counter electrode fabricated in Example 2.

### DESCRIPTION OF THE PREFERRED EMBODIMENTS

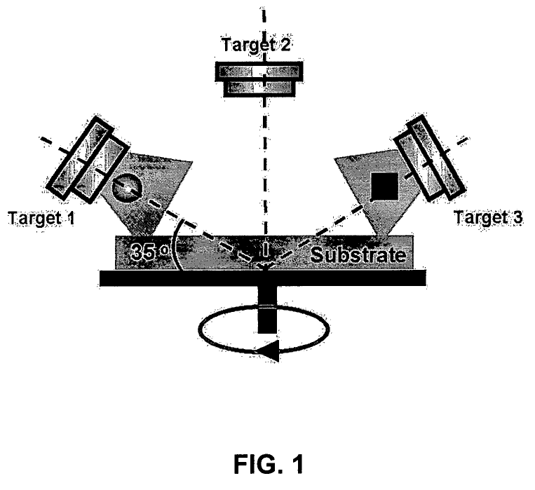

A co-sputtering system employed to fabricate a counter electrode in the present invention is shown in FIG. 1. Referring to FIG. 1, the co-sputtering system is similar to a conventional sputtering system, except that at least two sputtering guns are used in place of one sputtering gun. In some embodiments of the present invention, a co-sputtering process is conducted by placing platinum and a metal oxide as target materials in a conventional RF magnetron sputtering system and applying the respective RF powers to the target materials to simultaneously evaporate the target materials. Referring again to FIG. 1, as targets 1 and 3, platinum and a metal oxide are used. Both side target guns are inclined relative to a substrate at an angle of 35°. When two RF powers are applied to targets 1 and 3, respectively, plasma formation and simultaneous evaporation of the target materials are carried out.

The primary benefits of dye-sensitized solar cells are low manufacturing costs and environmentally friendliness. To reduce the manufacturing costs of the dye-sensitized solar cells, the platinum electrode used as a counter electrode must be fabricated at a low cost. The fabrication of a counter electrode comprising platinum and a metal oxide of the present invention can lower the fabrication costs to 40% or less, compared to the conventional platinum counter electrodes, based on the same active surface area. Accordingly, the use of the counter electrode comprising platinum and a metal oxide deposited on the surface of a substrate enables the manufacture of a highly efficient solar cell at a low cost.

The ratio of the platinum to the metal oxide added varies depending on the respective RF powers applied to the target materials, evaporation time and the distance between the targets and the substrate. The weight ratio of the platinum to the metal oxide can be in the range of about 0.3-0.5:1, but is not limited thereto.

The method of the present invention will now be described in more detail with reference to the following preferred examples using an RF magnetron sputtering system.

A substrate used in the present invention for the evaporation process using an RF magnetron sputtering system can be a glass plate coated with fluorine-doped tin oxide (SnO₂), and has a resistivity of 7 Ω/m. As target materials, platinum and a metal oxide are used. RF powers applied to the target materials are controlled depending on the characteristics of the oxide. Where the platinum target is arranged in the center of a chamber and the metal oxide target is arranged at one side of the chamber, evaporation is carried out. Argon (Ar) gas is fed into the system during evaporation to a pressure of 5×10⁻³ torr.

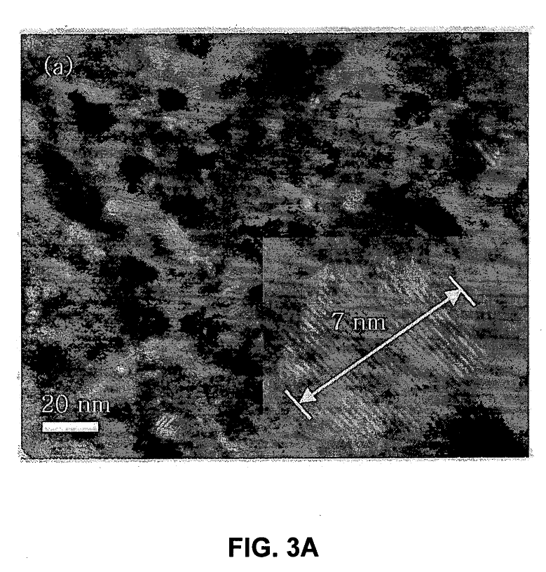

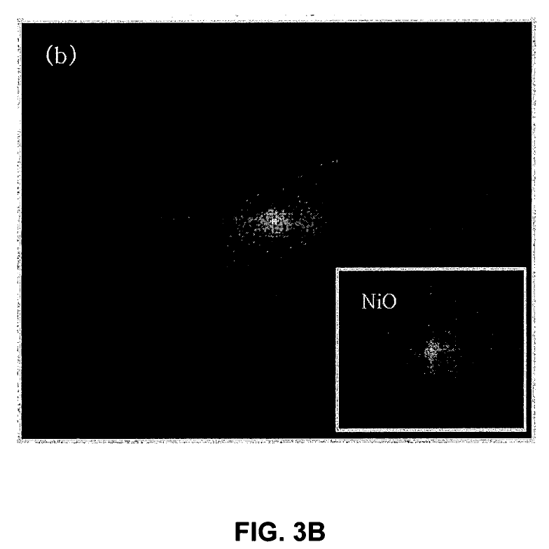

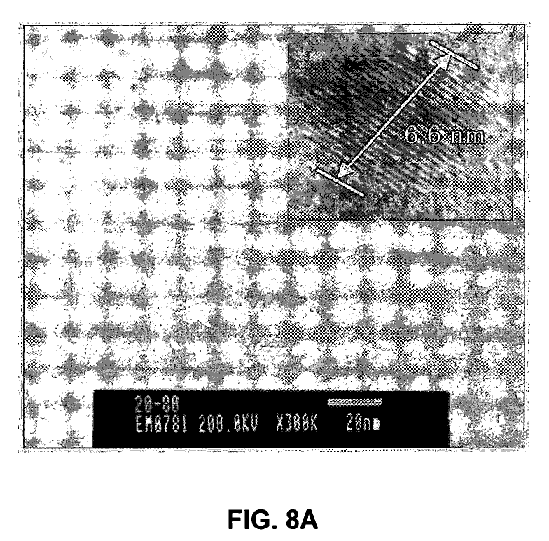

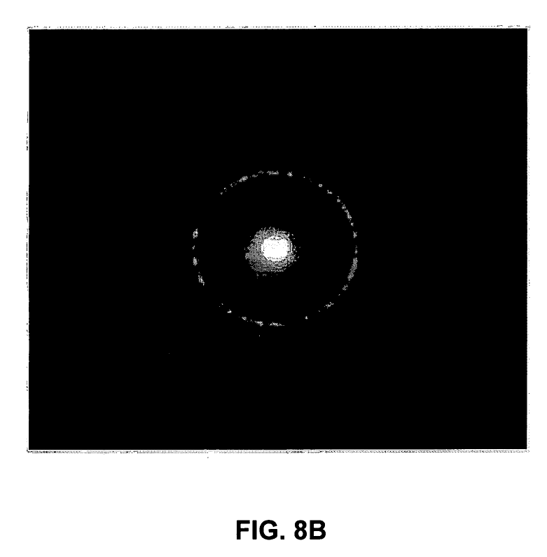

As can be seen from FIGS. 3 and 8, a counter electrode fabricated in accordance with the method of the present invention includes nanocrystalline platinum having a size of about 7 nm and an amorphous metal oxide deposited on the surface of the substrate (nickel oxide is shown in FIG. 3 and titanium oxide is shown in FIG. 8). A solar cell manufactured using such a counter electrode is highly efficient, compared to conventional solar cells manufactured using platinum counter electrodes. This is because the formation of the nanocrystalline platinum increases the active surface area and the use of the highly refractive metal oxide as a target material increases the reflectance of light.

The present invention will now be described in more detail with reference to the following examples. These examples are given for the purpose of illustration and are not to be construed as limiting the scope of the invention.

### EXAMPLE 1

### Fabrication of Platinum-Nickel Oxide (Pt—NiO) Counter Electrode

In this example, an electrode comprising nanocrystalline platinum and amorphous nickel oxide deposited on a surface of a substrate was fabricated using a co-sputtering system (RF magnetron sputtering system, Samwon Vacuum Co., Ltd., Korea) under Ar atmosphere. A glass plate coated with fluorine-doped tin oxide (SnO₂) during evaporation was used as a substrate. Where a platinum target was arranged in the center of a chamber, and a nickel oxide target was arranged at one side of the chamber, RF powers of 30 W and 40 W were applied for 2 minutes to evaporate the two targets, respectively. In order to prepare a test piece for the transmission electron microscope (TEM) and transmission electron diffraction measurements of the electrode, a Cu grid was added to the substrate during evaporation. In addition, in order to compare the characteristics of the platinum-nickel oxide, a platinum electrode was fabricated using the same system. At this time, an RF powder of 30 W was applied to the platinum for 2 minutes to evaporate the platinum.

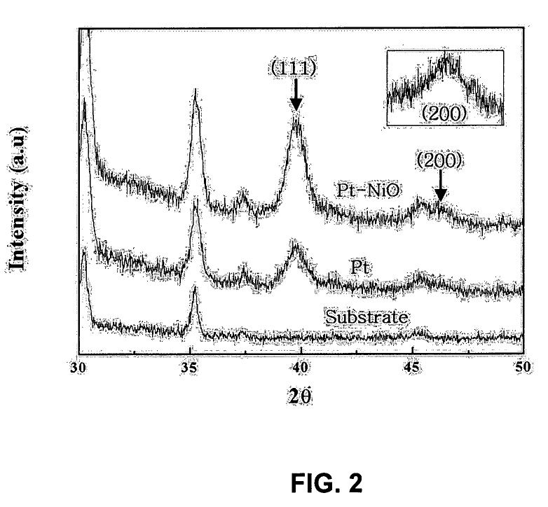

The structural analysis of the two electrodes thus fabricated was performed by the X-ray diffraction (XRD) shown in FIG. 2. Referring to FIG. 2, in the case of the platinum electrode, (111) and (200) diffraction peaks of platinum were observed at angles of 39.8° and 46.2°, respectively. This presence of the peaks reveals that polycrystalline platinum was formed on the substrate. On the other hand, in the case of the platinum-nickel oxide electrode, (111) and (200) diffraction peaks were observed at angles of 39.8° and 46.2°, respectively. The absence of characteristic peaks of nickel oxide indicates that amorphous nickel oxide and polycrystalline platinum coexisted in the electrode.

As can be seen from the transmission electron microscope (TEM) image shown in FIG. 3A and the transmission electron diffraction (TED) pattern shown in FIG. 3B, nanocrystalline platinum having a crystal size of 7 nm and amorphous nickel oxide coexist in the electrode.

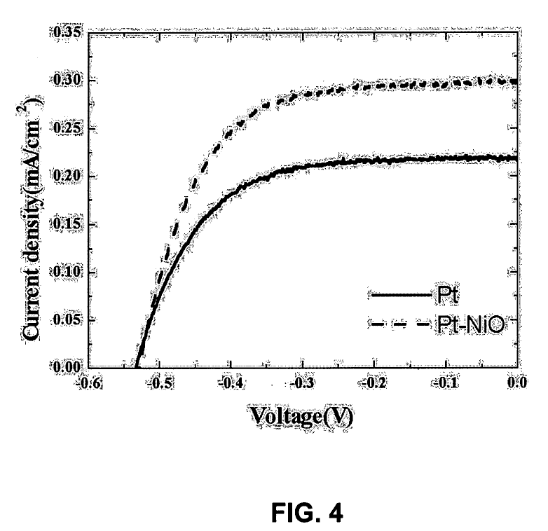

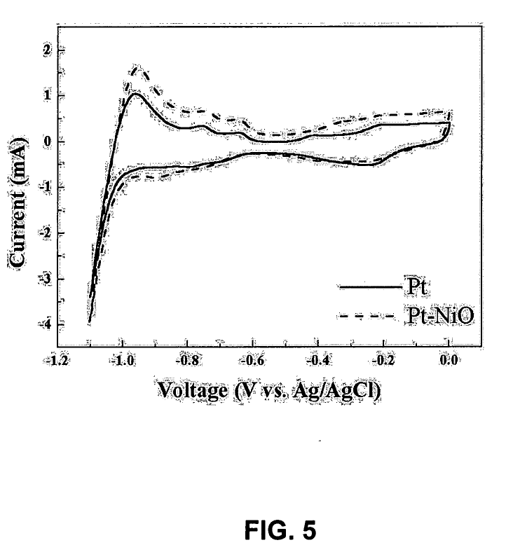

In order to evaluate the characteristics of the counter electrodes thus fabricated, polyethylene oxide-based all-solid-state dye-sensitized solar cells were manufactured using the counter electrodes. The performance of the solar cells was evaluated by measuring the current-voltage (I—V) characteristics of the solar cells as shown in FIG. 4. As a result, the solar cell manufactured using the platinum-nickel oxide electrode as a counter electrode exhibited improved efficiency by 37%, compared to the solar cell manufactured using the platinum electrode. This improvement is based on the increase in the active surface area of the counter electrode due to the formation of the nanocrystalline platinum. The increase in the active surface area was confirmed through the cyclic voltammogram (CV) shown in FIG. 5.

### EXAMPLE 2

### Fabrication of Platinum-Titanium (Pt—TiO₂) Counter Electrode

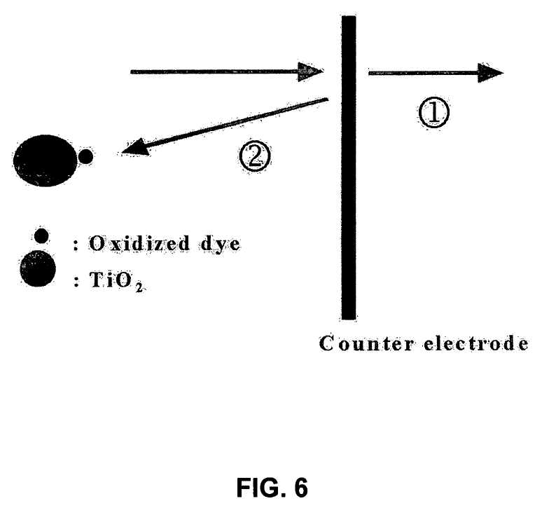

In this example, an electrode comprising nanocrystalline platinum and amorphous titanium oxide deposited on the surface of a substrate was fabricated using the same system employed in as Example 1 under Ar atmosphere. Since the electrode was fabricated using the titanium oxide having a high refractive index, it exhibited a high reflectance. This improvement in reflectance causes the excitation of a dye and thus increases the efficiency of a solar cell to be manufactured. The principle is explained in FIG. 6.

A glass plate coated with fluorine-doped tin oxide (SnO₂) during evaporation was used as a substrate. Where a platinum target was arranged in the center of a chamber, and a titanium oxide target was arranged at one side of the chamber, RF powers of 20 W and 80 W were applied for 2 minutes to evaporate the two targets, respectively. In order to prepare a test piece for the transmission electron microscope (TEM) and transmission electron diffraction measurements of the electrode, a Cu grid was added to the substrate during evaporation. In addition, in order to compare the characteristics of the platinum-titanium oxide, a platinum electrode was fabricated using the same system. At this time, an RF powder of 20 W was applied to the platinum for 2 minutes to evaporate the platinum.

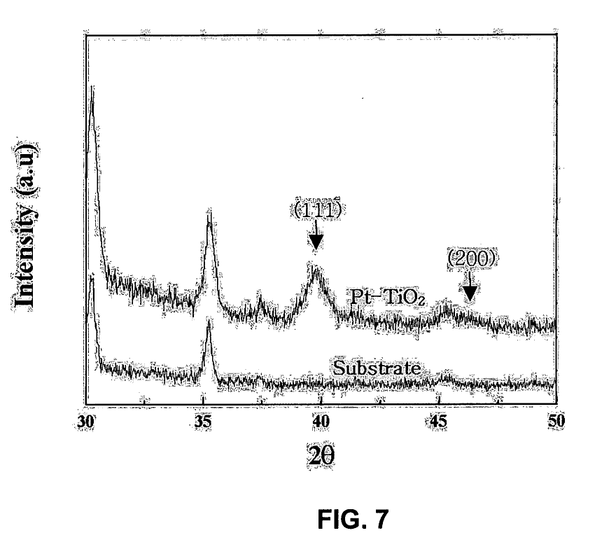

The structural analysis of the two electrodes thus fabricated was performed by the X-ray diffraction (XRD) shown in FIG. 7. Referring to FIG. 2, in the case of the platinum electrode, (111) and (200) diffraction peaks of platinum were observed at angles of 39.8° and 46.2°, respectively. This presence of the peaks reveals that polycrystalline platinum was formed on the substrate. On the other hand, in the case of the platinum-titanium oxide electrode, (111) and (200) diffraction peaks were observed at angles of 39.8° and 46.2°, respectively. The absence of characteristic peaks of titanium oxide indicates that amorphous titanium oxide and polycrystalline platinum coexisted in the electrode.

As can be seen from the transmission electron microscope (TEM) image shown in FIG. 8A and the transmission electron diffraction (TED) pattern shown in FIG. 8B, nanocrystalline platinum having a crystal size of 7 nm and amorphous titanium oxide coexist in the electrode.

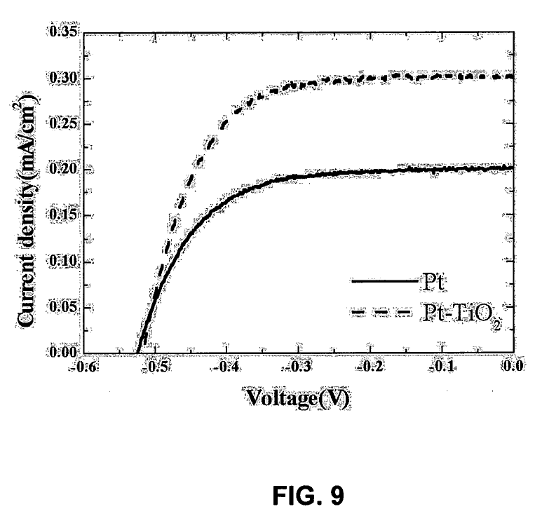

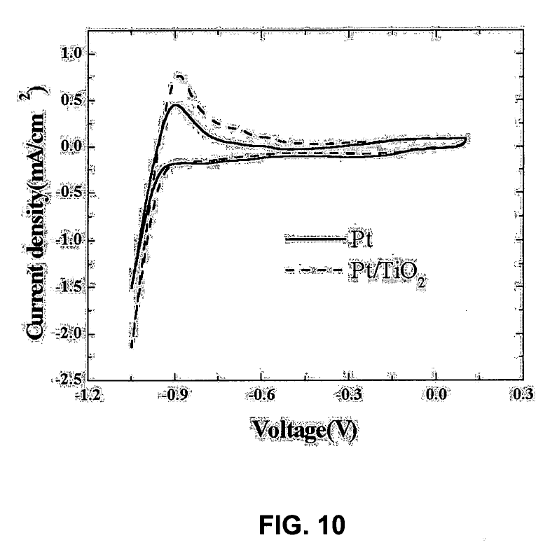

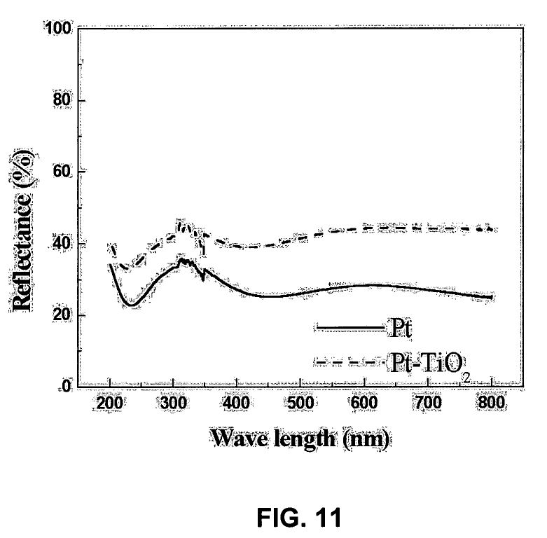

In order to evaluate the characteristics of the counter electrodes thus fabricated, polyethylene oxide-based all-solid-state dye-sensitized solar cells were manufactured using the counter electrodes. The performance of the solar cells was evaluated by measuring the current-voltage (I—V) characteristics of the solar cells shown in FIG. 9. As a result, the solar cell manufactured using the platinum-titanium oxide electrode as a counter electrode exhibited improved efficiency by 49%, compared to the solar cell manufactured using the platinum electrode. This improvement of efficiency is based on the increase in the active surface area of the counter electrode due to the formation of the nanocrystalline platinum and increase in the reflectance due to the use of the highly refractive titanium oxide as a target material. The increase in the active surface area was confirmed through the cyclic voltammogram (CV) shown in FIG. 10, and the increase in the reflectance was confirmed through the reflectance measurement graph shown in FIG. 11.

As is apparent from the foregoing, the method of the present invention provides a counter electrode comprising nanocrystalline platinum having a size of a few nanometers and an amorphous metal oxide deposited on the surface of a substrate. In addition, since all-solid-state dye-sensitized solar cells manufactured using the counter electrode exhibit increased active surface area and reflectance, the efficiency of the solar cells is greatly improved.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

All documents cited herein are hereby incorporated by reference in their entirety to the same extent as if each individual document was specifically and individually indicated to be incorporated by reference in its entirety.

1. A method for fabricating a counter electrode for a dye-sensitized solar cell, the method comprising:
co-sputtering platinum and a metal oxide as target materials onto a substrate; and
forming a counter electrode including nanocrystalline platinum and an amorphous metal oxide on the substrate.

2. The method of claim 1, wherein the metal oxide has a refractive index of 2 or higher.

3. The method of claim 1, wherein the metal oxide is selected from oxides of titanium, chromium, zinc, copper, ruthenium, vanadium, tin and indium.

4. The method of claim 1, wherein the metal oxide has an electric conductivity of at least 0.1 S/m.

5. The method of claim 1, wherein the metal oxide has an open structure.

6. The method of claim 1, wherein the metal oxide is an open-structured transition metal.

7. The method of claim 6, wherein the metal oxide is selected from oxides of tantalum, silicon, and aluminum.

8. A method for fabricating a counter electrode, the method comprising:
sputtering platinum onto a substrate to form nanocrystalline platinum on the substrate;
sputtering a metal oxide onto the substrate to form an amorphous metal oxide on the substrate; and
forming an electrode from the nanocrystalline platinum and the amorphous metal oxide on the substrate.

9. The method of claim 8, wherein the metal oxide has a refractive index of 2 or higher.

10. The method of claim 8, wherein the metal oxide is selected from oxides of titanium, chromium, zinc, copper, ruthenium, vanadium, tin and indium.

11. The method of claim 8, wherein the metal oxide has an electric conductivity of at least 0.1 S/m.

12. The method of claim 8, wherein the metal oxide has an open structure.

13. The method of claim 8, wherein the metal oxide is an open-structured transition metal.

14. The method of claim 13, wherein the metal oxide is selected from oxides of tantalum, silicon, and aluminum.
